(19) United States
(12) Patent Application Publication
(10) Pub. No.: US 2013/0153903 A1
(43) Pub. Date: Jun. 20, 2013

(54) AMBIPOLAR TRANSISTOR DEVICE STRUCTURE AND METHOD OF FORMING THE SAME

(71) Applicants: Chao-Feng Sung, Miaoli County (TW); Yen-Min Hsieh, Miaoli County (TW)

(72) Inventors: Chao-Feng Sung, Miaoli County (TW); Yen-Min Hsieh, Miaoli County (TW)

(73) Assignee: INDUSTRIAL TECHNOLOGY RESEARCH INSTITUTE, Hsinchu (TW)

(21) Appl. No.: 13/451,549

(22) Filed: Apr. 20, 2012

(30) Foreign Application Priority Data
Dec. 16, 2011 (TW) 100146908

(51) Int. Cl. H01L 29/772; H01L 21/336

(52) U.S. Cl. 257/57; 438/285; 438/299; 438/151; 438/155; 257/E29.242; 257/E21.409

(57) ABSTRACT

An ambipolar transistor device structure suitable for use in an integrated circuit is disclosed. An electron blocking layer or a hole blocking layer is interposed between a source/drain and an ambipolar active layer. Therefore, a unipolar device electric property may be extracted from the ambipolar active layer, which may be suitably applied to the design of a logic circuit. The manufacturing method of the disclosure is simple, only needing one patterning step, so as to effectively improve the performance of the ambipolar device.

### CROSS-REFERENCE TO RELATED APPLICATION

This application claims the priority benefit of Taiwan application serial no. 100146908, filed on Dec. 16, 2011. The entirety of the above-mentioned patent application is hereby incorporated by reference herein and made a part of this specification.

### TECHNICAL FIELD

The disclosure relates to a semiconductor device and a method of forming the same.

### BACKGROUND

An inverter is a basic device used in an integrated circuit for inverting the phase of an input signal by 180 degrees. Inverters are often used in analog circuits, such as audio amplifiers and clock oscillators. Inverters are often used in electronic circuit design.

In general, there are two methods of manufacture for inverters used in integrated circuits. The first method of manufacture is manufacturing a unipolar inverter. Two unipolar transistors (two PMOSs or two NMOSs) directly form a complementary logic circuit. The single-type PMOS or NMOS is used for direct construction, where the source/drain needs one kind of metal, and an active layer material needs a single-type (either P-type or N-type) of material. This method simplifies the manufacturing process but its disadvantages are that the signal is easily distorted, and the power consumption is high.

The second manner of manufacture, in which N-type and P-type organic film transistors are connected in series to form a complementary inverter circuit, is more commonly used. This manner has the advantage of low power consumption, high reliability and high noise tolerance. The disadvantage is that it is rather difficult to manufacture the N-type and the P-type active layers on the same substrate, and also the necessity of performing individual patterning processes makes it difficult to prevent the material of each layer from being damaged.

By selecting and forming an active layer where negative/positive carriers are transmitted simultaneously, a single active layer may be used to manufacture an ambipolar field effect transistor (FET) to complete a CMOS inverter circuit. Because the ambipolar FET simultaneously possesses electron transmission and hole transmission properties, its device on/off ratio is low. Detectable current generation occurs in the ambipolar FET during operation in a low electric field. Therefore, when the ambipolar FETs are connected in series into an inverter, the gain of the inverter is excessively low so as to limit its application.

### SUMMARY

One of the embodiments provides an ambipolar transistor device structure, comprising a gate disposed on a substrate, a source and a drain disposed on the substrate and located at two sides of the gate, a dielectric layer disposed between the gate and each of the source and the drain, an ambipolar semiconductor layer at least disposed between the source and the drain and a carrier blocking layer disposed between the ambipolar semiconductor layer and each of the source and the drain.

Another embodiment provides a manufacturing method of forming an ambipolar transistor device structure, comprising forming a source and a drain on a substrate, forming a carrier blocking layer and an ambipolar semiconductor layer on the substrate and at least between the source and the drain, forming a dielectric layer on the ambipolar semiconductor layer, and forming a gate on the dielectric layer between the source and the drain, wherein the dielectric layer isolates the gate, the source and the drain from each other.

Another embodiment provides a manufacturing method of forming an ambipolar transistor device structure, comprising providing a substrate in which the substrate has a first region and a second region, forming a first source and a first drain on the substrate in the first region, forming a first carrier blocking material layer, an ambipolar semiconductor material layer and a second carrier blocking material layer on the substrate in the first region and the second region, patterning the first carrier blocking material layer, the ambipolar semiconductor material layer and the second carrier blocking material layer so as to form a first stack structure covering the first source and the first drain on the substrate in the first region and form a second stack structure on the substrate in the second region, forming a second source and a second drain on the second stack structure, forming a dielectric layer on the substrate to cover the first stack structure and the second stack structure, forming a first gate on the dielectric layer between the first source and the first drain and forming a second gate on the dielectric layer between the second source and the second drain.

Another embodiment provides a method of forming an ambipolar transistor device structure comprising forming an ambipolar semiconductor layer and a carrier blocking layer on a substrate, forming a source and a drain on the carrier blocking layer, forming a dielectric layer on the substrate to cover the source and the drain, and forming a gate on the dielectric layer between the source and the drain.

The disclosure additionally provides a method of forming an ambipolar transistor device structure comprising forming a gate on a substrate, forming a dielectric layer on the substrate to cover the gate, forming a source and a drain on the dielectric layer at two sides of the gate, and forming a carrier blocking layer and an ambipolar semiconductor layer on the dielectric layer and at least between the source and the drain.

The disclosure also provides a method of forming an ambipolar transistor device structure comprising forming a gate on a substrate, forming a dielectric layer on the substrate to cover the gate, and forming an ambipolar semiconductor layer and a carrier blocking layer on the dielectric layer. A source and a drain are formed on the carrier blocking layer at two sides of the gate.

The disclosure further provides a method of forming an ambipolar transistor device structure comprising providing a substrate, in which the substrate has a first region and a second region, forming a first gate on the substrate in the first region and a second gate on the substrate in the second region, forming a dielectric layer on the substrate to cover the first gate and the second gate, forming a first source and a first drain on the dielectric layer in the first region, and forming a first carrier blocking material layer, an ambipolar semiconductor material layer and a second carrier blocking material layer on the substrate in the first region and the second region. The first carrier blocking material layer, the ambipolar semiconductor material layer and the second carrier blocking material layer are patterned, so as to form a first stack structure covering the first source and the first drain on the substrate in the first region and form a second stack structure on the substrate in the second region, and forming a second source and a second drain on the second stack structure.

Based on the above description, in the ambipolar transistor device structure of the disclosure, an electron blocking layer or a hole blocking layer is interposed between a source/drain and an ambipolar active layer. Therefore, a unipolar device electric property may be extracted from the ambipolar active layer, which may be suitably applied to the design of a logic circuit. The manufacturing method of the disclosure is simple, N-type and P-type semiconductor layers may be simultaneously defined only needing one patterning step, so as to effectively improve the performance of the ambipolar device.

### BRIEF DESCRIPTION OF THE DRAWINGS

FIGS. 1A and 1B are schematic cross-sectional views of a method of forming an ambipolar transistor device structure according to a first embodiment of the disclosure.

FIGS. 2A and 2B are schematic cross-sectional views of a method of forming an ambipolar transistor device structure according to a second embodiment of the disclosure.

FIGS. 3A and 3B are schematic cross-sectional views of a method of forming an ambipolar transistor device structure according to a third embodiment of the disclosure.

FIG. 3B-1 is a schematic cross-sectional view of an ambipolar transistor device structure according to the third embodiment of the disclosure.

FIGS. 4A and 4B are schematic cross-sectional views of a method of forming an ambipolar transistor device structure according to a fourth embodiment of the disclosure.

FIG. 4B-1 is a schematic cross-sectional view of an ambipolar transistor device structure according to the fourth embodiment of the disclosure.

FIGS. 5A to 5C are schematic cross-sectional views of a method of forming an ambipolar transistor device structure according to a fifth embodiment of the disclosure.

FIGS. 6A to 6C are schematic cross-sectional views of a method of forming an ambipolar transistor device structure according to a sixth embodiment of the disclosure.

FIG. 6C-1 is a schematic cross-sectional view of an ambipolar transistor device structure according to the sixth embodiment of the disclosure.

FIG. 7 is an I_{d}-V_{g} curve of organic FETs of Example 1 and Comparative Example 1.

FIG. 8 is an I_{d}-V_{g} curve of organic FETs of Example 2 and Comparative Example 1.

FIG. 9 is an I_{d}-V_{g} curve of organic FETs of Example 3 and Comparative Example 1.

Common reference numerals are used throughout the drawings and the detailed description to indicate the same elements. The present invention will be more apparent from the following detailed description taken in conjunction with the accompanying drawings.

### DETAILED DESCRIPTION

The disclosure provides an ambipolar transistor device structure, in which a carrier blocking layer (such as an electron blocking layer or a hole blocking layer) is interposed between a source/drain and an ambipolar semiconductor layer. The carrier injection is limited according to the property of the blocking layer, so as to further determine that the conductivity type of the device is N-type or P-type. In such manner, a unipolar device electric property may be extracted from the ambipolar semiconductor layer so that its device operation is similar to that of a unipolar FET. Accordingly, the manufacturing process is simplified, and such unipolar electric property is suitably applied to design of a logic circuit.

Because the ambipolar transistor device may have an upper gate structure or a lower gate structure, there are four different device structures according to disposition relations between components, which are illustrated below with a first embodiment to a fourth embodiment respectively. A fifth and sixth embodiment illustrate the innovative structure of the disclosure used to manufacture a CMOS inverter.

### First Embodiment

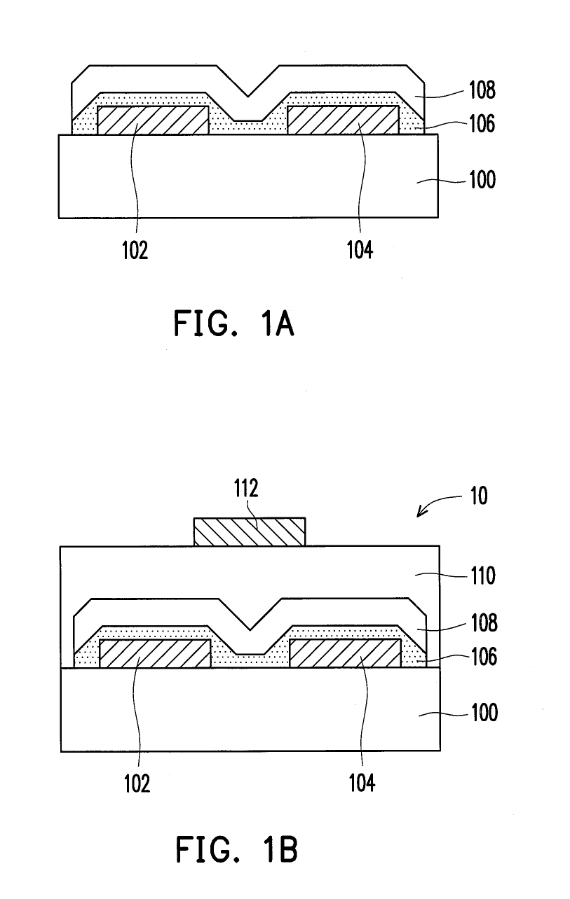

FIGS. 1A and 1B are schematic cross-sectional views of a method of forming an ambipolar transistor device structure according to a first embodiment of the disclosure.

Referring to FIG. 1A, a source 102 and a drain 104 are formed on a substrate 100. The substrate 100 may be a hard substrate or a flexible substrate. The material of the hard substrate can be, but is not limited to, glass, quartz or silicon wafer. The material of the flexible substrate can be, but is not limited to, plastic such as acrylic, metal foil or paper. A method of forming the source 102 and the drain 104 includes forming a metal layer (not shown) on the substrate 100, and then patterning the metal layer through lithography and etching processes. The material of the metal layer can be, but is not limited to, gold, silver, copper, aluminum, molybdenum, chromium or an alloy thereof. A method of forming the metal layer includes performing a physical vapor deposition process, such as an evaporation method. In another embodiment, the source 102 and the drain 104 may also be directly formed on the substrate 100 through a conductive ink jet printing method or a suitable transfer technology.

A carrier blocking layer 106 and an ambipolar semiconductor layer 108 are formed on the substrate 100 and at least between the source 102 and the drain 104. In this embodiment, the carrier blocking layer 106 and the ambipolar semiconductor layer 108 cover the source 102, the drain 104, and a channel region between the source 102 and the drain 104. A method of forming the carrier blocking layer 106 and the ambipolar semiconductor layer 108 includes forming the carrier blocking material layer, an ambipolar semiconductor material layer and a patterned photoresist layer (not shown) on the substrate 100. An etching process is performed on the carrier blocking material layer and the ambipolar semiconductor material layer by using a patterned photoresist layer as a mask, so as to remove a portion of the carrier blocking material layer and a portion of the ambipolar semiconductor material layer. The patterned photoresist layer is removed.

The method of forming the carrier blocking material layer includes performing a physical vapor deposition process, such as an evaporation method. The ambipolar semiconductor material layer may be formed by individually evaporating an N-type organic semiconductor material and a P-type organic semiconductor material, evaporating or sputtering an N-type inorganic semiconductor material and a P-type inorganic semiconductor material, co-evaporating an N-type organic semiconductor material and a P-type organic semiconductor material, or evaporating an organic semiconductor material with an ambipolar property.

The carrier blocking layer 106 may be an electron blocking layer. The electron blocking layer may be formed of an inorganic material, and the inorganic material can be, but is not limited to, WO₃, V₂O₅ or MoO₃. The electron blocking layer may also be formed of an organic material, and the organic material can be, but is not limited to, 4′,4″-tris(N-3-methylphenyl-N-phenylamino)triphenylamine (m-MTDATA) or bis(2-methyl-8-quinolinolato-N1,O8)-(1,1′-biphenyl-4-olato) aluminum (BALq).

The carrier blocking layer 106 may also be a hole blocking layer. The hole blocking layer may be formed of an inorganic material, and the inorganic material can be, but is not limited to, LiF, CsF or TiO₂. The hole blocking layer may also be formed of an organic material, and the organic material can be, but is not limited to, 2,9-dimethyl-4,7-diphenyl-1,10-phenanthroline (BCP).

Ambipolar semiconductor material of the disclosure refers to a material whose hole property and electron property are mutually “balanced”. In an embodiment, the ambipolar semiconductor layer 108 is formed by stacking an N-type organic semiconductor material and a P-type organic semiconductor material. The N-type organic semiconductor material can be, but is not limited to, N,N′-ditridecyl-3,4,9,10-perylene tetracarboxylic diimide (PTCDI-C13), C₆₀ or [6,6]-phenyl-C61-butyric acid methyl ester (PCBM). The P-type organic semiconductor material can be, but is not limited to, pentacene or poly(3-hexylthiophene) (P3HT). The N-type organic semiconductor material and the P-type organic semiconductor material can be formed for example, with an evaporation method. In another embodiment, the ambipolar semiconductor layer 108 can be formed by mixing an N-type organic semiconductor material and a P-type organic semiconductor material. The ambipolar semiconductor layer 108 can be formed by mixing the N-type organic semiconductor material and the P-type organic semiconductor material with a solution process or a co-evaporation method. In still another embodiment, the ambipolar semiconductor layer 108 is formed of an organic semiconductor material with an ambipolar property. The organic semiconductor material with the ambipolar property can be, but is not limited to, PDPP-TBT, or 8,9,10,11-tetrachloro-6,13-bis(triisopropylsilylethynyl)-1-azapentacene, and a forming method thereof includes performing an evaporation method or a solution process. In another embodiment, the ambipolar semiconductor layer 108 is formed by stacking an N-type inorganic semiconductor material and a P-type inorganic semiconductor material, and a forming method thereof includes performing a sputtering method. The N-type inorganic semiconductor material can be, but is not limited to, IGZO, and the P-type inorganic semiconductor material can be, but is not limited to, SnO.

Referring to FIG. 1B, a dielectric layer 110 is formed on the ambipolar semiconductor layer 108. In this embodiment, the dielectric layer 110 covers the carrier blocking layer 106 and the ambipolar semiconductor layer 108. A method of forming the dielectric layer 110 includes forming a dielectric material layer (not shown) on the substrate 100, and then patterning the dielectric material layer through lithography and etching processes. The dielectric layer 110 may include an inorganic dielectric material or an organic dielectric material. The inorganic dielectric material can be, but is not limited to, silicon oxide or silicon nitride. The organic dielectric material can be, but is not limited to, polyvinyl pyrrolidone (PVP) or parylene. A method of forming the dielectric material layer includes performing a chemical vapor deposition method, a spin-coating method or an evaporation method.

A gate 112 is formed on the dielectric layer 110 between the source 102 and the drain 104, in which the dielectric layer 110 isolates the gate 112, the source 102 and the drain 104 from each other. A method of forming the gate 112 includes forming a gate material layer (not shown), and then patterning the gate material layer through lithography and etching processes. The material of the gate material layer can be, but is not limited to, gold, silver, copper, aluminum, molybdenum, chromium or an alloy thereof. A method of forming the gate material layer includes performing a physical vapor deposition process, such as an evaporation method. In another embodiment, the gate 112 may also be directly formed on the substrate 100 through a conductive ink jet printing method or a suitable transfer technology.

A passivation layer (not shown) may be formed on the substrate 100 to cover the gate 112 and the dielectric layer 110.

As shown in FIG. 1B, the ambipolar transistor device structure 10 of the first embodiment is an upper gate structure, including the substrate 100, the source 102, the drain 104, the carrier blocking layer 106, the ambipolar semiconductor layer 108, the dielectric layer 110 and the gate 112. The source 102, the drain 104 and the gate 112 are all disposed on the substrate 100, and the gate 112 is located above the source 102 and the drain 104. The source 102 and the drain 104 are located at two sides of the gate 112. The dielectric layer 110 is disposed between the gate 112 and each of the source 102 and the drain 104. The ambipolar semiconductor layer 108 is at least disposed between the source 102 and the drain 104. In this embodiment, the ambipolar semiconductor layer 108 further extends above the source 102 and the drain 104. Specifically, the ambipolar semiconductor layer 108 covers the source 102, the drain 104, and a channel region between the source 102 and the drain 104. The carrier blocking layer 106 is disposed between the ambipolar semiconductor layer 108 and each of the source 102 and the drain 104.

When the ambipolar transistor device structure 10 is used as a P-type FET, in order to block electrons from passing and allow holes to be injected, the carrier blocking layer 106 may be an electron blocking layer. When the ambipolar transistor device structure 10 is used as an N-type FET, in order to block holes from passing and allow electrons to be injected, the carrier blocking layer 106 may be a hole blocking layer. In this way, extracting a unipolar device electric property from the ambipolar semiconductor layer 108 may be achieved.

### Second Embodiment

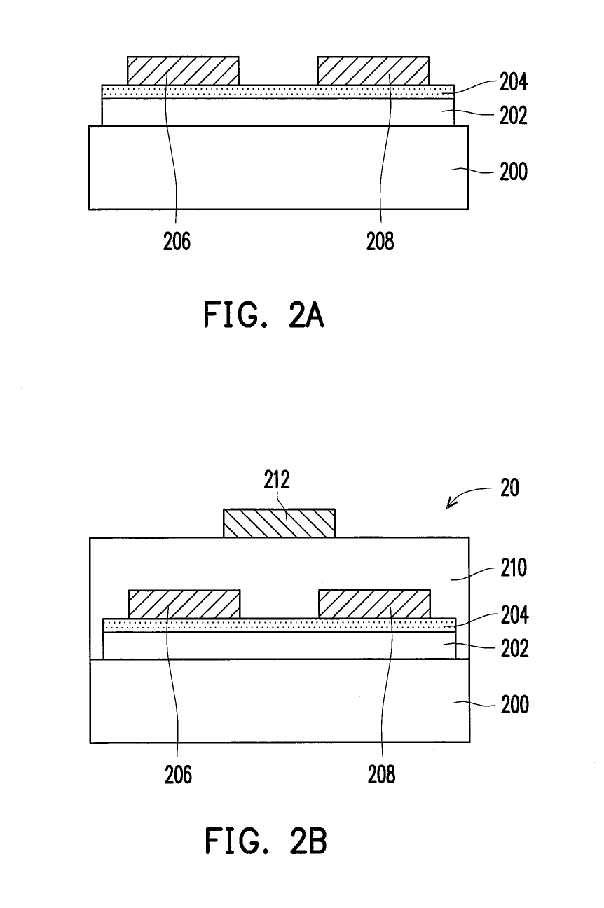

FIGS. 2A and 2B are schematic cross-sectional views of a method of forming an ambipolar transistor device structure according to a second embodiment of the disclosure.

Referring to FIG. 2A, an ambipolar semiconductor layer 202 and a carrier blocking layer 204 are formed on a substrate 200. A method of forming the ambipolar semiconductor layer 202 and the carrier blocking layer 204 includes forming an ambipolar semiconductor material layer, the carrier blocking material layer and a patterned photoresist layer (not shown) on the substrate 200. An etching process is performed on the ambipolar semiconductor material layer and the carrier blocking material layer by using the patterned photoresist layer as a mask, so as to remove a portion of the ambipolar semiconductor material layer and a portion of the carrier blocking material layer. The patterned photoresist layer is removed. The ambipolar semiconductor material layer may be formed by individually evaporating an N-type organic semiconductor material and a P-type organic semiconductor material, evaporating or sputtering an N-type inorganic semiconductor material and a P-type inorganic semiconductor material, co-evaporating an N-type organic semiconductor material and a P-type organic semiconductor material, or evaporating an organic semiconductor material with an ambipolar property. A method of forming the carrier blocking material layer includes performing a physical vapor deposition process, such as an evaporation method. The materials of the substrate 200, the ambipolar semiconductor layer 202 and the carrier blocking layer 204 of the second embodiment are similar to those of the substrate 100, the ambipolar semiconductor layer 108 and the carrier blocking layer 106 of the first embodiment.

In an embodiment, an insulating layer and a surface modification layer (not shown) may also be formed between the substrate 200 and the ambipolar semiconductor layer 202. The insulating layer may be, but is not limited to, a silicon oxide layer formed with a thermal oxidation method. The surface modification layer may be, but is not limited to, amorphous perfluorinated resin (brand name: CYTOP) formed with a spin-coating method. A source 206 and a drain 208 are formed on the carrier blocking layer 204.

Referring to FIG. 2B, a dielectric layer 210 is formed on the substrate 200 to cover the source 206 and the drain 208. A gate 212 is formed on the dielectric layer 210 between the source 206 and the drain 208.

As shown in FIG. 2B, the ambipolar transistor device structure 20 of the second embodiment is an upper gate structure, including the substrate 200, the ambipolar semiconductor layer 202, the carrier blocking layer 204, the source 206, the drain 208, the dielectric layer 210 and the gate 212. The source 206, the drain 208 and the gate 212 are all disposed on the substrate 200, and the gate 212 is located above the source 206 and the drain 208. The source 206 and the drain 208 are located at two sides of the gate 212. The dielectric layer 210 is disposed between the gate 212 and each of the source 206 and the drain 208. The ambipolar semiconductor layer 202 is at least disposed between the source 206 and the drain 208. In this embodiment, the ambipolar semiconductor layer 202 further extends below the source 206 and the drain 208. The ambipolar semiconductor layer 202 extends outwardly from the channel region between the source 206 and the drain 208 and extends below the source 206 and the drain 208. The carrier blocking layer 204 is disposed between the ambipolar semiconductor layer 202 and each of the source 206 and the drain 208.

When the ambipolar transistor device structure 20 is used as a P-type FET, the carrier blocking layer 204 may be an electron blocking layer. Alternatively, when the ambipolar transistor device structure 20 is used as an N-type FET, the carrier blocking layer 204 may be a hole blocking layer. In such manner, the purpose of extracting a unipolar device electric property from the ambipolar semiconductor layer 202 may be achieved.

### Third Embodiment

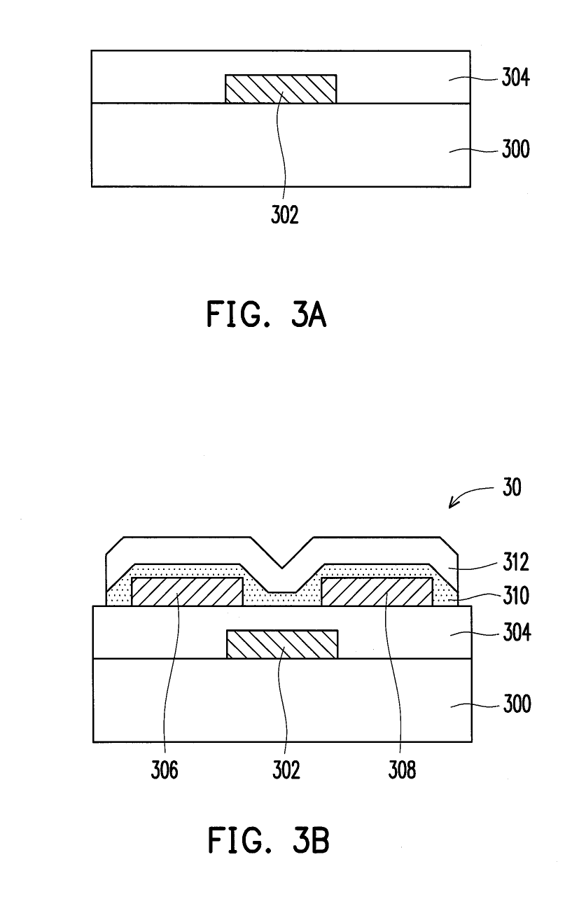

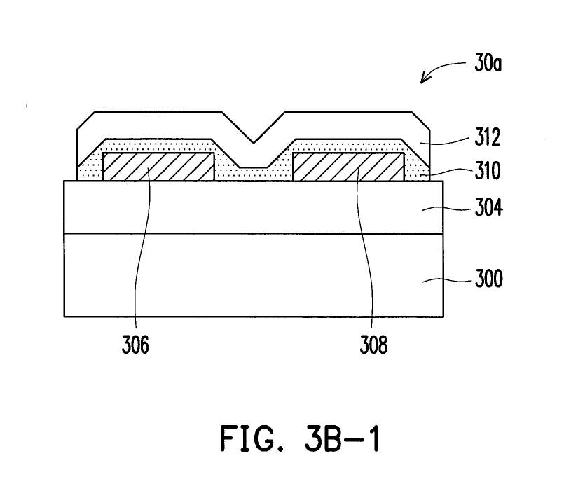

FIGS. 3A and 3B are schematic cross-sectional views of a method of forming an ambipolar transistor device structure according to a third embodiment of the disclosure.

Referring to FIG. 3A, a gate 302 is formed on a substrate 300. Afterward, a dielectric layer 304 is formed on the substrate 300 to cover the gate 302. Referring to FIG. 3B, a source 306 and a drain 308 are formed on the dielectric layer 304 at two sides of the gate 302. A carrier blocking layer 310 and an ambipolar semiconductor layer 312 are formed on the dielectric layer 304 and at least between the source 306 and the drain 308.

As shown in FIG. 3B, the ambipolar transistor device structure 30 of the third embodiment is a lower gate structure, including the substrate 300, the gate 302, the dielectric layer 304, the source 306, the drain 308, the carrier blocking layer 310 and the ambipolar semiconductor layer 312. The gate 302, the source 306 and the drain 308 are all disposed on the substrate 200, and the gate 112 is located below the source 306 and the drain 308. The source 306 and the drain 308 are located at two sides of the gate 302. The dielectric layer 304 is disposed between the gate 302 and each of the source 306 and the drain 308. The ambipolar semiconductor layer 312 is at least disposed between the source 306 and the drain 308. In this embodiment, the ambipolar semiconductor layer 312 further extends above the source 306 and the drain 308. The ambipolar semiconductor layer 312 covers the source 306, the drain 308, and a channel region between the source 306 and the drain 308. The carrier blocking layer 310 is disposed between the ambipolar semiconductor layer 312 and each of the source 306 and the drain 308.

In the ambipolar transistor device structure 30 of FIG. 3B, the case that the gate 302 is formed on a glass substrate 300 is taken as an example for illustration, but the disclosure is not limited thereto. In another embodiment, when the substrate 300 is a silicon substrate, the step of forming the gate 302 may be omitted, and the substrate 300 serves as a gate, as shown in an ambipolar transistor device structure 30a of FIG. 3B-1.

When the ambipolar transistor device structure 30 is used as a P-type FET, the carrier blocking layer 310 may be an electron blocking layer. Alternatively, when the ambipolar transistor device structure 30 is used as an N-type FET, the carrier blocking layer 310 may be a hole blocking layer. In such manner, the purpose of extracting a unipolar device electric property from the ambipolar semiconductor layer 312 may be achieved.

### Fourth Embodiment

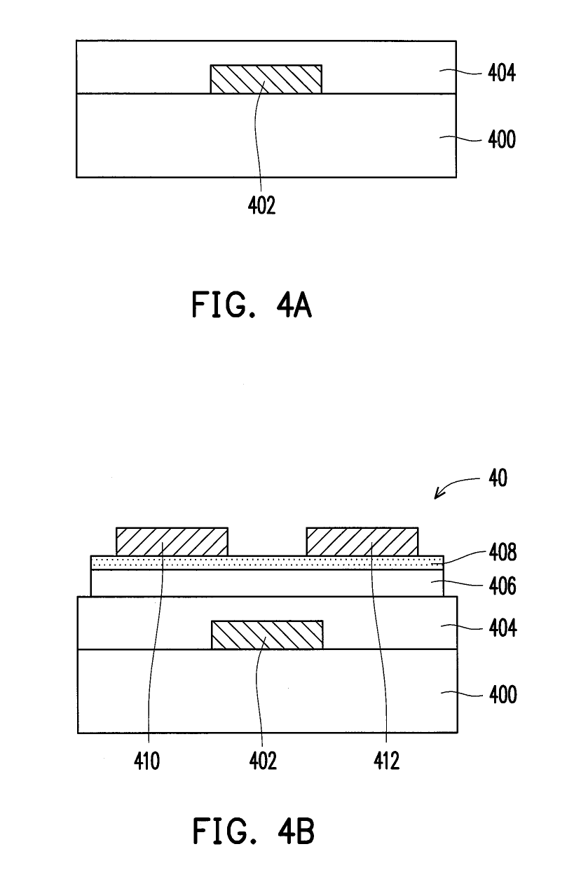

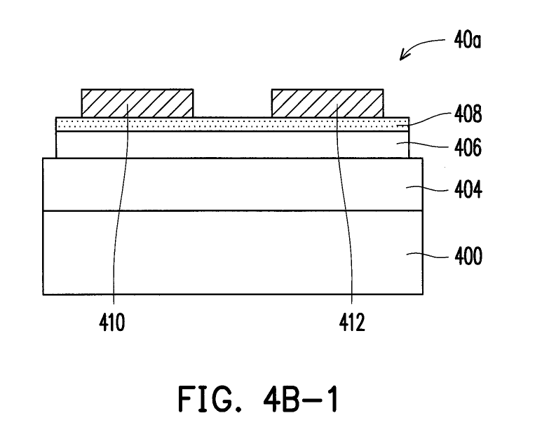

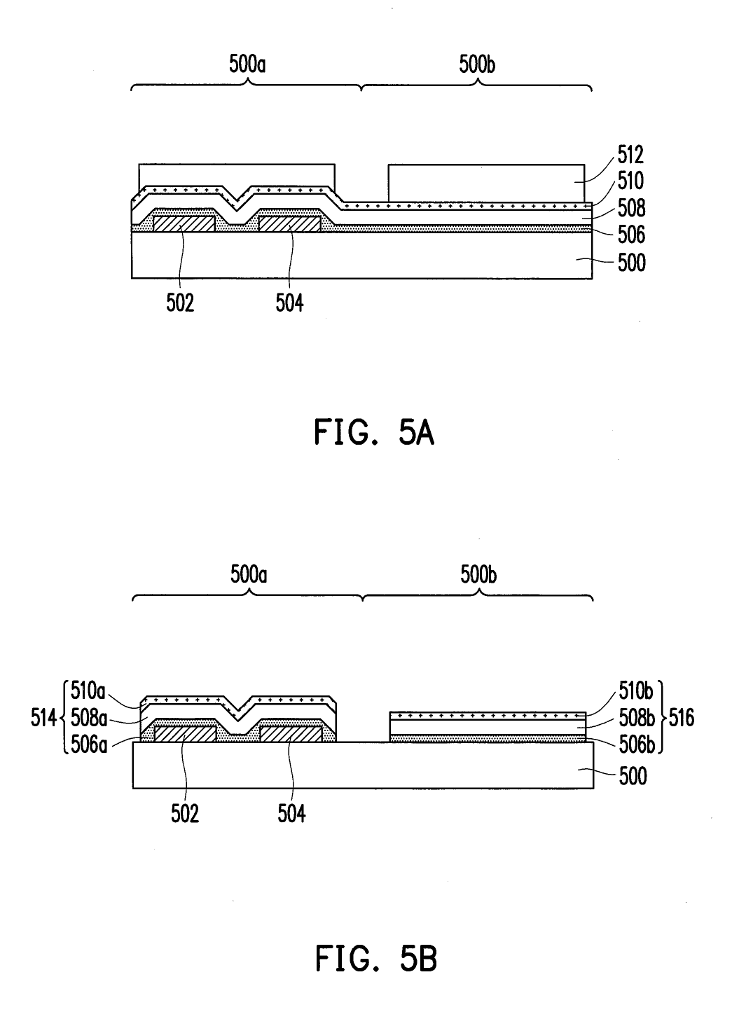

FIGS. 4A and 4B are schematic cross-sectional views of a method of forming an ambipolar transistor device structure according to a fourth embodiment of the disclosure.

Referring to FIG. 4A, a gate 402 is formed on a substrate 400. A dielectric layer 404 is formed on the substrate 400 to cover the gate 402. Referring to FIG. 4B, an ambipolar semiconductor layer 406 and a carrier blocking layer 408 are formed on a dielectric layer 404. A method of forming the ambipolar semiconductor layer 406 and the carrier blocking layer 408 includes forming an ambipolar semiconductor material layer, the carrier blocking material layer and a patterned photoresist layer (not shown) on the substrate 400. An etching process is performed on the ambipolar semiconductor material layer and the carrier blocking material layer by using the patterned photoresist layer as a mask, so as to remove a portion of the ambipolar semiconductor material layer and a portion of the carrier blocking material layer. The patterned photoresist layer is removed. The ambipolar semiconductor material layer may be formed by individually evaporating an N-type organic semiconductor material and a P-type organic semiconductor material, evaporating or sputtering an N-type inorganic semiconductor material and a P-type inorganic semiconductor material, co-evaporating an N-type organic semiconductor material and a P-type organic semiconductor material, or evaporating an organic semiconductor material with an ambipolar property. A method of forming the carrier blocking material layer includes performing a physical vapor deposition process, such as an evaporation method.

A source 410 and a drain 412 are formed on the carrier blocking layer 408 at two sides of the gate 402. As shown in FIG. 4B, the ambipolar transistor device structure 40 of the fourth embodiment is a lower gate structure, including the substrate 400, the gate 402, the dielectric layer 404, the ambipolar semiconductor layer 406, the carrier blocking layer 408, the source 410 and the drain 412. The gate 402, the source 410 and the drain 412 are all disposed on the substrate 400, and the gate 402 is located below the source 410 and the drain 412. The source 410 and the drain 412 are located at two sides of the gate 402. The dielectric layer 404 is disposed between the gate 402 and each of the source 410 and the drain 412. The ambipolar semiconductor layer 406 is at least disposed between the source 410 and the drain 412. In this embodiment, the ambipolar semiconductor layer 406 further extends below the source 410 and the drain 412. Specifically, the ambipolar semiconductor layer 406 extends outwardly from the channel region between the source 410 and the drain 412 and extends below the source 410 and the drain 412. The carrier blocking layer 408 is disposed between the ambipolar semiconductor layer 406 and each of the source 410 and the drain 412.

In the ambipolar transistor device structure 40 of FIG. 4B, the case that the gate 402 is formed on a glass substrate 400 is taken as an example for illustration, but the disclosure is not limited thereto. In another embodiment, when the substrate 400 is a silicon substrate, the step of forming the gate 402 may be omitted, and the substrate 400 serves as a gate, as shown in an ambipolar transistor device structure 40a of FIG. 4B-1.

When the ambipolar transistor device structure 40 is used as a P-type FET, the carrier blocking layer 408 may be an electron blocking layer. Alternatively, when the ambipolar transistor device structure 40 is used as an N-type FET, the carrier blocking layer 408 may be a hole blocking layer. In such manner, the purpose of extracting a unipolar device electric property from the ambipolar semiconductor layer 406 may be achieved.

The innovative structure of the disclosure may be used to manufacture a CMOS inverter, wherein a P-type FET and an N-type FET may be manufactured simultaneously by performing only one patterning step on an ambipolar semiconductor layer. The manufacturing process is greatly simplified and the competitive advantage is achieved. Two embodiments are listed for illustration as follows.

### Fifth Embodiment

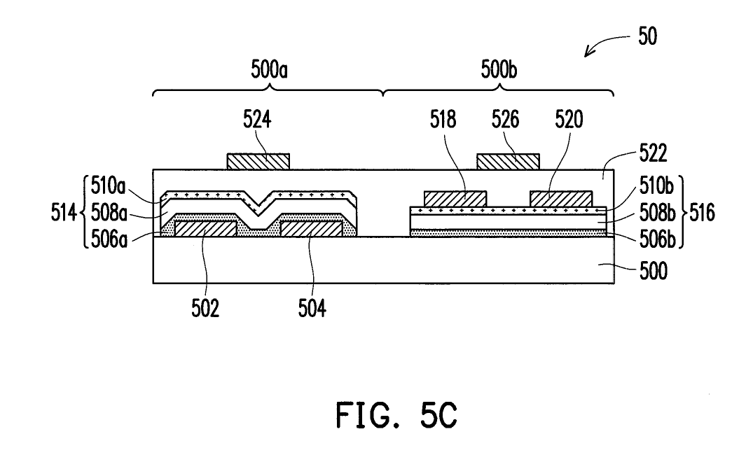

FIGS. 5A to 5C are schematic cross-sectional views of a method of forming an ambipolar transistor device structure according to a fifth embodiment of the disclosure.

Referring to FIG. 5A, a substrate 500 is provided. The substrate 500 has a first region 500a and a second region 500b. The substrate 500 may be a hard substrate or a flexible substrate. A source 502 and a drain 504 are formed on the substrate 500 in the first region 500a. A carrier blocking material layer 506, an ambipolar semiconductor material layer 508, a carrier blocking material layer 510 and a patterned photoresist layer 512 are formed on the substrate 500 in the first region 500a and the second region 500b.

The carrier blocking material layers 506 and 510 may respectively be an electron blocking material layer and a hole blocking material layer (or an electron blocking material layer and a hole blocking material layer). A method of forming each of the carrier blocking material layers 506 and 510 includes performing a physical vapor deposition process, such as an evaporation method. The ambipolar semiconductor material layer 508 may be formed by individually evaporating an N-type organic semiconductor material and a P-type organic semiconductor material, evaporating or sputtering an N-type inorganic semiconductor material and a P-type inorganic semiconductor material, co-evaporating an N-type organic semiconductor material and a P-type organic semiconductor material, or evaporating an organic semiconductor material with an ambipolar property.

Then, referring to FIG. 5B, the carrier blocking material layer 506, the ambipolar semiconductor material layer 508 and the carrier blocking material layer 510 are patterned by using the patterned photoresist layer 512 as a mask, so as to form a stack structure 514 covering the source 502 and the drain 504 on the substrate in the first region 500a and to form a stack structure 516 on the substrate 500 in the second region 500b. The foregoing patterning step includes an etching process. The stack structure 514 includes (from bottom to top) a carrier blocking layer 506a, an ambipolar semiconductor layer 508a and a carrier blocking layer 510a. The stack structure 516 includes (from bottom to top) a carrier blocking layer 506b, an ambipolar semiconductor layer 508b and a carrier blocking layer 510b. Then, the patterned photoresist layer 512 is removed.

Referring to FIG. 5C, a source 518 and a drain 520 are formed on the stack structure 516 in the second region 500b. A dielectric layer 522 is formed on the substrate 500 to cover the stack structure 514 and the stack structure 516. A gate 524 is formed on the dielectric layer 522 between the source 502 and the drain 504, and a gate 526 is formed on the dielectric layer 522 between the source 518 and the drain 520.

In an embodiment, when the first region 500a is a P-type device region and the second region 500b is an N-type device region, the carrier blocking material layer 506 is an electron blocking material layer, and the carrier blocking material layer 510 is a hole blocking material layer. The electric property of the formed device is determined by the carrier blocking layer (electron blocking layer or hole blocking layer) between the source/drain and the ambipolar active layer. Therefore, when the carrier blocking material layer 506 is an electron blocking material layer and the carrier blocking material layer 510 is a hole blocking material layer, the first region 500a is a P-type device region and the carrier blocking layer 510a (hole blocking layer) in the first region 500a does not function; and the second region 500b is an N-type device region and the carrier blocking layer 506b (electron blocking layer) in the second region 500b does not function.

In another embodiment, when the first region 500a is an N-type device region and the second region 500b is a P-type device region, the carrier blocking material layer 506 is a hole blocking material layer, and the carrier blocking material layer 510 is an electron blocking material layer.

Therefore, a one-pass patterning process may be used to simultaneously define N-type and P-type semiconductor layers. The method of forming the ambipolar transistor device structure of the disclosure simplifies the manufacturing process, and reduces the influence of the patterning process on the semiconductor material, so as to effectively improve the performance of the ambipolar device.

### Sixth Embodiment

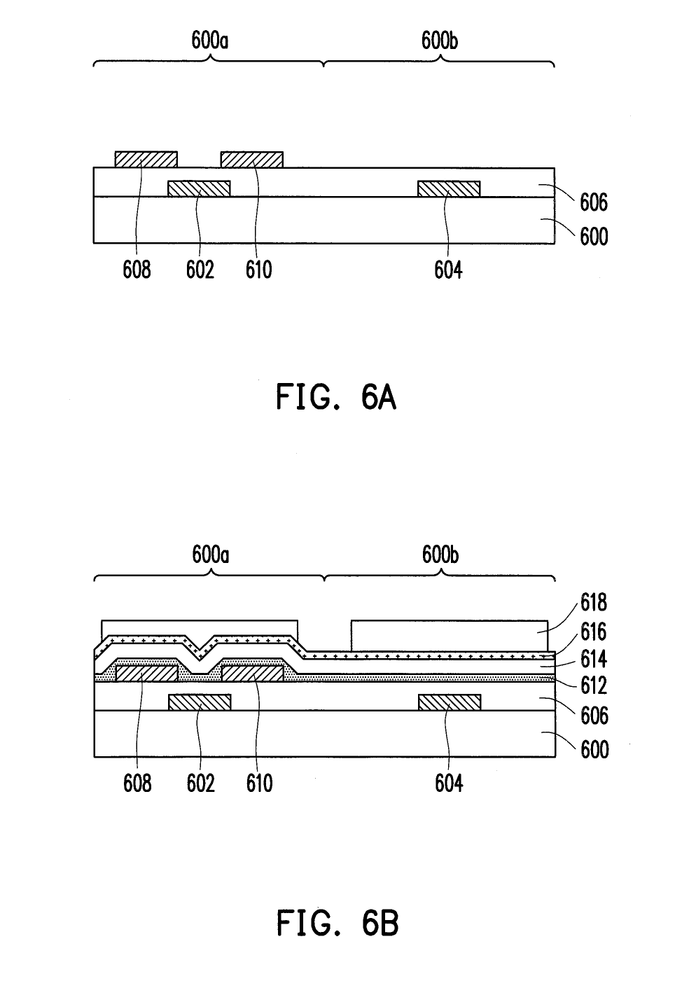

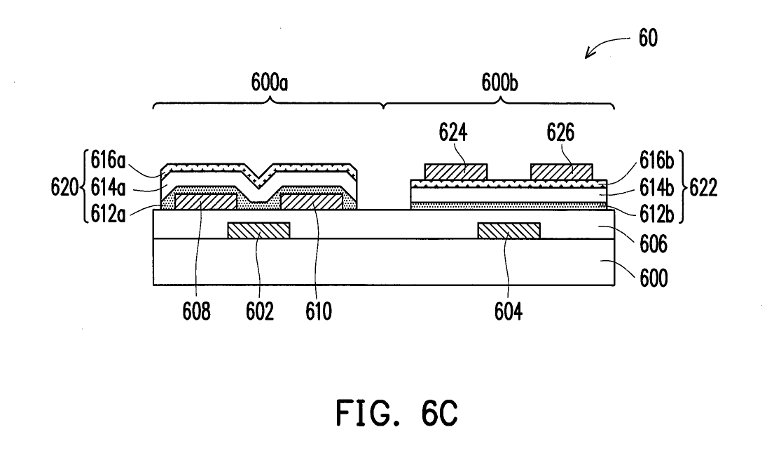

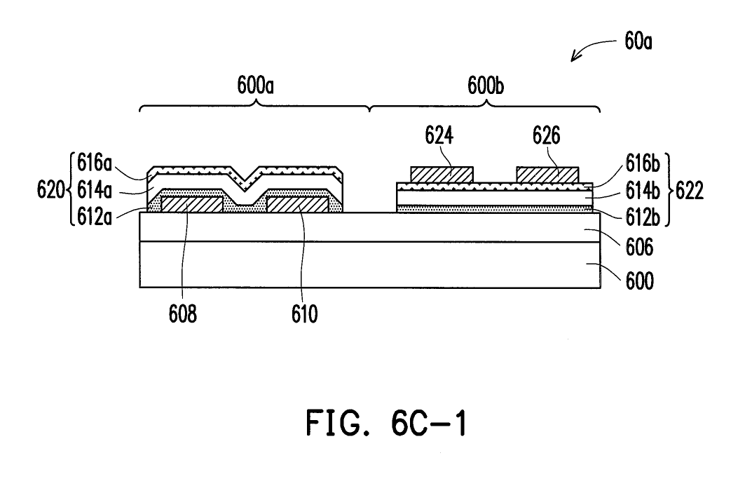

FIGS. 6A to 6C are schematic cross-sectional views of a method of forming an ambipolar transistor device structure according to a sixth embodiment of the disclosure.

Referring to FIG. 6A, a substrate 600 is provided. The substrate 600 has a first region 600a and a second region 600b. Afterward, a gate 602 is formed on the substrate 600 in the first region 600a, and a gate 604 is formed on the substrate 600 in the second region 600b. A dielectric layer 606 is formed on the substrate 600 to cover the gate 602 and the gate 604. A source 608 and a drain 610 are formed on the dielectric layer 606 in the first region 600a. A channel region between the source 608 and the drain 610 corresponds to the gate 602.

Referring to FIG. 6B, a carrier blocking material layer 612, an ambipolar semiconductor material layer 614, a carrier blocking material layer 616 and a patterned photoresist layer 618 are formed on the substrate 600 in the first region 600a and the second region 600b.

Referring to FIG. 6C, the carrier blocking material layer 612, the ambipolar semiconductor material layer 614 and the carrier blocking material layer 616 are patterned by using the patterned photoresist layer 618 as a mask, so as to form a stack structure 620 covering the source 608 and the drain 610 on the substrate 600 in the first region 600a and to form a stack structure 622 on the substrate 600 in the second region 600b. The stack structure 620 includes (from bottom to top) a carrier blocking layer 612a, an ambipolar semiconductor layer 614a and a carrier blocking layer 616a. The stack structure 622 includes (from bottom to top) a carrier blocking layer 612b, an ambipolar semiconductor layer 614b and a carrier blocking layer 616b. The patterned photoresist layer 618 is removed. A source 624 and a drain 626 are formed on the stack structure 622. A channel region between the source 624 and the drain 626 corresponds to the gate 604.

In the ambipolar transistor device structure 60 of FIG. 6C, the case that the gate 602 and the gate 604 are formed on a glass substrate 600 is taken as an example for illustration, but the disclosure is not limited thereto. In another embodiment, when the substrate 600 is a silicon substrate, the step of forming the gate 602 and the gate 604 may be omitted, and the substrate 600 serves as a gate, as shown in an ambipolar transistor device structure 60a of FIG. 6C-1.

In an embodiment, when the first region 600a is a P-type device region and the second region 600b is an N-type device region, the carrier blocking material layer 612 is an electron blocking material layer, and the carrier blocking material layer 616 is a hole blocking material layer.

In another embodiment, when the first region 600a is an N-type device region and the second region 600b is a P-type device region, the carrier blocking material layer 612 is a hole blocking material layer, and the carrier blocking material layer 616 is an electron blocking material layer.

Therefore, a one-pass patterning process may be used to simultaneously define N-type and P-type semiconductor layers, so as to simplify the manufacturing process and reduce the influence of the patterning process on the semiconductor material.

### Example 1

A substrate adopts a P-type silicon wafer (30 to 60 Ω-cm, <100> crystal panel). Then, 300 nm silicon oxide as an insulating layer is formed on the substrate through a thermal oxidation method. Afterward, a 800 Å CYTOP film as a surface modification layer is coated on the substrate by a spin-coating method. Then, the substrate is placed in a vacuum chamber which is pumped to 2.5×10⁻⁶ torr, and by use of a BN crucible at a deposit rate of 0.5 to 1 Å/sec, PTCDI-C13 as an N-type organic semiconductor material and pentacene as a P-type organic semiconductor material are separately evaporated on the substrate, so as to form an ambipolar semiconductor layer. In this case, the thickness of the film is monitored with a quartz oscillator, and then is corrected with a white light interferometer, so as to form a 450 Å PTCDI-C13 film and a 500 Å pentacene film. Then, a 500 Å m-MTDATA film as an electron blocking layer is evaporated on the ambipolar semiconductor layer. Subsequently, a source and a drain (gold electrodes) are formed on the electron blocking layer. A P-type organic FET of Example 1 is thus completed, as shown in FIG. 4B-1. The device channel width is 200 μm, and the device channel length is 2,000 μm.

The LUMO of the pentacene film and the PTCDI film is only about 3.2 eV to 3.4 eV, and the work function of gold is about 5.1 eV, so the m-MTDATA film having the LUMO of 1.9 eV can effectively block electron transmission, and is suitable to serve as the electron blocking layer of this device.

### Example 2

A device is fabricated according to the same manner as that of Example 1, but a hole blocking layer (BCP film) replaces the electron blocking layer (m-MTDATA film) of Example 1, and silver electrodes are used to replace the gold electrodes of Example 1 and used as the source and the drain. An N-type organic FET of Example 2 is thus completed.

The HOMO of the pentacene film and the PTCDI film is only about 5.0 eV to 5.4 eV, and the work function of silver is about 4.26 eV, so the BCP film having the HOMO of 6.7 eV can effectively block hole transmission, and is suitable to serve as the hole blocking layer of this device.

### Example 3

A substrate adopts a P-type silicon wafer (30 to 60)-cm, <100> crystal panel), which has a P-type device region and an N-type device region. Then, 300 nm silicon oxide as an insulating layer is formed on the substrate through a thermal oxidation method. Afterward, a 800 Å CYTOP film as a surface modification layer is coated on the substrate through a spin-coating method. Then, a source and a drain (gold electrodes) are formed on the substrate in the P-type device region. Then, the substrate is placed in a vacuum chamber which is pumped to 2.5×10⁻⁶ torr, and by use of a BN crucible at a deposit rate of 0.5 to 1 Å/sec, a 500 Å m-MTDATA film as an electron blocking layer, a PTCDI-C13 film (450 Å) and a pentacene film (500 Å) as an ambipolar semiconductor material layer, and a 500 Å PCB film as a hole blocking layer are separately evaporated on the substrate. Afterward, a patterning process is performed, so as to simultaneously define active layers of the P-type device region and the N-type device region. Subsequently, a drain and a source (silver electrodes) are formed on the substrate in the N-type device region. An organic FET as a CMOS inverter of Example 3 is thus completed, as shown in FIG. 6C-1.

### Comparative Example 1

An organic FET is fabricated according to a manner the same as that of Example 1, but no electron blocking layer is formed.

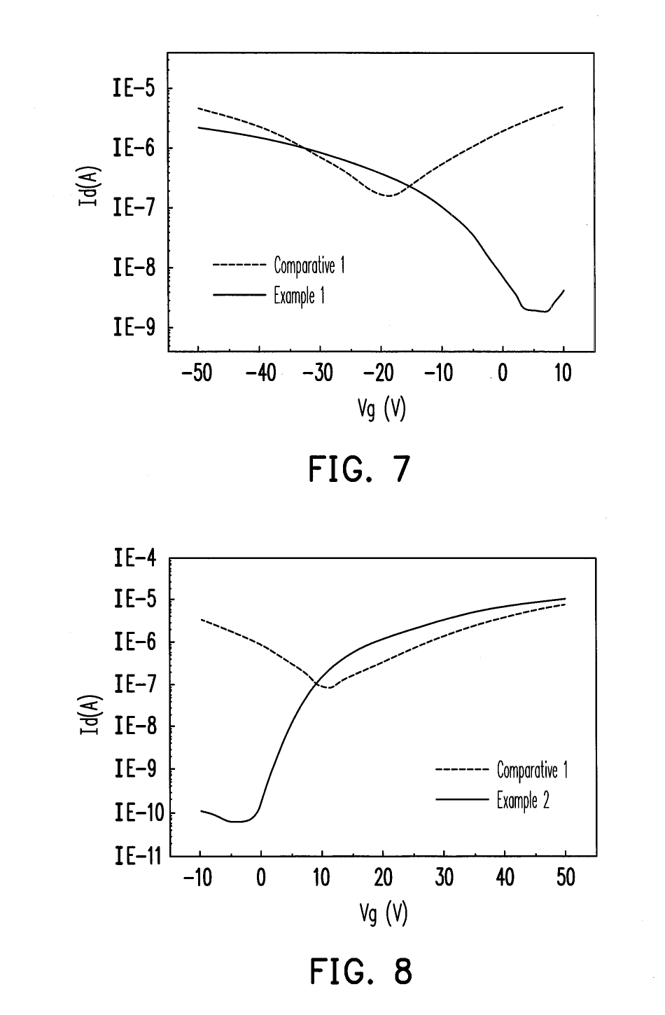

FIG. 7 is an I_{d}-V_{g} curve of organic FETs of Example 1 and Comparative Example 1. As shown in FIG. 7, a P-type gate (V_{g}) is scanned from −50 V to 10 V, and a drain (V_{d}) maintains being applied with a bias of −40 V. The solid line and the dashed line in the drawing represent organic FETs of Example 1 and Comparative Example 1 respectively.

It can be seen in the FIG. 7 that when an m-MTDATA electron blocking layer is added to the ambipolar transistor device, the current on/off ratio is greatly increased from 10 originally to 10³. The N-type off current (off current) after electron suppression also has a large operating range, which may make the device more stable, and the current does not greatly change when the applied voltage changes in a range of ±1 V. The P-type turn on voltage approximates to 0 V.

FIG. 8 is an I_{d}-V_{g} curve of organic FETs of Example 2 and Comparative Example 1. As shown in FIG. 8, an N-type gate (V_{g}) is scanned from −10 V to +50 V, and a drain (V_{d}) maintains being applied with a bias of +40 V. The solid line and the dashed line in the drawing represent organic FETs of Example 2 and Comparative Example 1 respectively.

When a BCP hole blocking layer is added to the ambipolar transistor device, the current on/off ratio is greatly increased from 10² originally to 10⁵. The P-type off current after hole suppression also has a large operating range, which may make the device more stable, and the current does not greatly change when the applied voltage just changes in a range of ±1 V. The N-type turn on voltage approximates to 0 V.

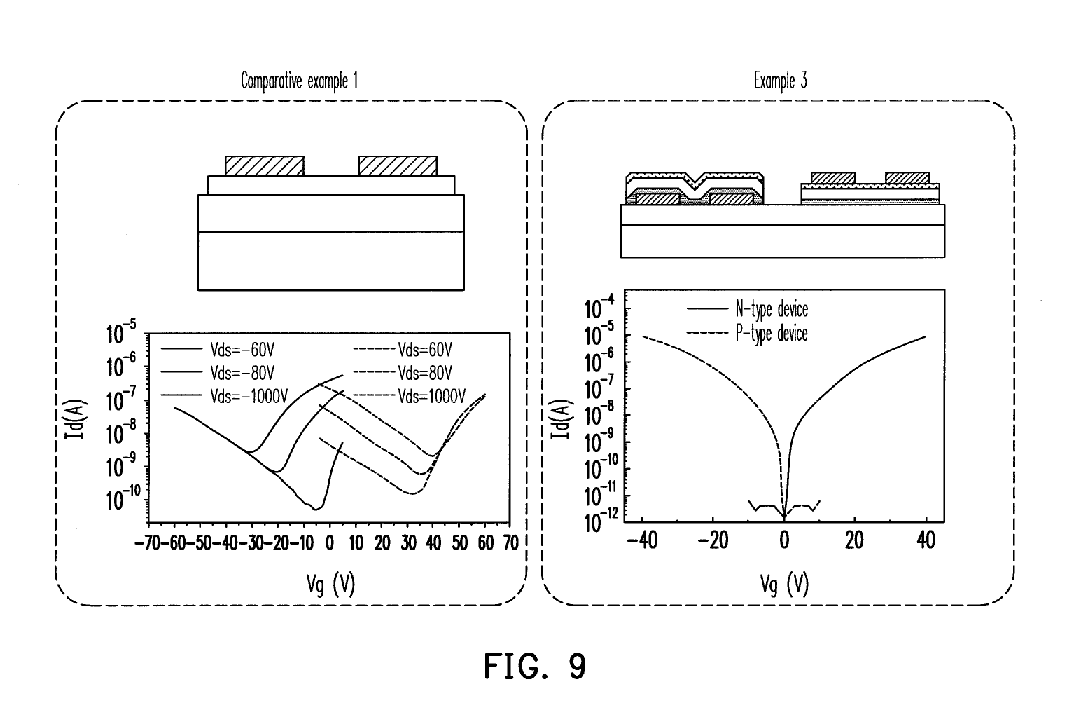

FIG. 9 is an I_{d}-V_{g} curve of organic FETs of Example 3 and Comparative Example 1. As shown in FIG. 9, the organic transistor in a conventional device of Comparative Example 1 has an ambipolar transmission property, so an apparent current is generated in a low electric field. Accordingly, the on/off ratio of the device is excessively low. On the contrary, the innovative structure of Example 3 provided in the disclosure may separately control electron/hole transmission properties of an ambipolar transistor by an appropriate arrangement of the carrier blocking layer and the electrode, so that no apparent current is generated in a low electric field, and the on/off ratio of the device is increased.

In an ambipolar transistor device structure of the disclosure, an electron blocking layer or hole blocking layer is interposed between a source/drain and an ambipolar active layer, therefore a unipolar device electric property may be extracted from an ambipolar semiconductor layer, so as to improve the practicability of an ambipolar semiconductor transistor, and greatly increase the current on/off ratio. Furthermore, the manufacturing method of the disclosure is simple, N-type and P-type semiconductor layers may be simultaneously defined only needing to perform a patterning step once, and the influence of patterning processes many times on the semiconductor materials in the prior art is reduced, so as to effectively improve the performance of the ambipolar device.

While the invention has been described and illustrated with reference to specific embodiments thereof, these descriptions and illustrations do not limit the invention. It should be understood by those skilled in the art that various changes may be made and equivalents may be substituted without departing from the true spirit and scope of the invention as defined by the appended claims. The illustrations may not necessarily be drawn to scale. There may be distinctions between the artistic renditions in the present disclosure and the actual apparatus due to manufacturing processes and tolerances. There may be other embodiments of the present invention which are not specifically illustrated. The specification and the drawings are to be regarded as illustrative rather than restrictive. Modifications may be made to adapt a particular situation, material, composition of matter, method, or process to the objective, spirit and scope of the invention. All such modifications are intended to be within the scope of the claims appended hereto. While the methods disclosed herein have been described with reference to particular operations performed in a particular order, it will be understood that these operations may be combined, sub-divided, or re-ordered to form an equivalent method without departing from the teachings of the invention. Accordingly, unless specifically indicated herein, the order and grouping of the operations are not limitations of the invention.

What is claimed is:

1. An ambipolar transistor device structure, comprising:
a gate, disposed on a substrate;
a source and a drain, disposed on the substrate and located at two sides of the gate;
a dielectric layer, disposed between the gate and each of the source and the drain;
an ambipolar semiconductor layer, at least disposed between the source and the drain; and
a carrier blocking layer, disposed between the ambipolar semiconductor layer and each of the source and the drain.

2. The ambipolar transistor device structure according to claim 1, wherein the source and the drain are located above the gate.

3. The ambipolar transistor device structure according to claim 2, wherein the ambipolar semiconductor layer further extends above the source and the drain.

4. The ambipolar transistor device structure according to claim 2, wherein the ambipolar semiconductor layer further extends below the source and the drain.

5. The ambipolar transistor device structure according to claim 1, wherein the gate is located above the source and the drain.

6. The ambipolar transistor device structure according to claim 5, wherein the ambipolar semiconductor layer further extends above the source and the drain.

7. The ambipolar transistor device structure according to claim 5, wherein the ambipolar semiconductor layer further extends below the source and the drain.

8. The ambipolar transistor device structure according to claim 1, wherein the ambipolar semiconductor layer is formed by stacking an N-type organic semiconductor material and a P-type organic semiconductor material.

9. The ambipolar transistor device structure according to claim 1, wherein the ambipolar semiconductor layer is formed by mixing an N-type organic semiconductor material and a P-type organic semiconductor material.

10. The ambipolar transistor device structure according to claim 1, wherein the ambipolar semiconductor layer is formed of an organic semiconductor material with an ambipolar property.

11. The ambipolar transistor device structure according to claim 1, wherein the ambipolar semiconductor layer is formed by stacking an N-type inorganic semiconductor material and a P-type inorganic semiconductor material.

12. The ambipolar transistor device structure according to claim 1, wherein the carrier blocking layer is an electron blocking layer.

13. The ambipolar transistor device structure according to claim 12, wherein the electron blocking layer is formed of an inorganic material, and the inorganic material comprises WO₃, V₂O₅ or MoO₃.

14. The ambipolar transistor device structure according to claim 12, wherein the electron blocking layer is formed of an organic material, and the organic material comprises 4′,4″-tris(N-3-methylphenyl-N-phenylamino)triphenylamine (m-MTDATA) or bis(2-methyl-8-quinolinolato-N1,O8)-(1,1′-biphenyl-4-olato) aluminum (BALq).

15. The ambipolar transistor device structure according to claim 1, wherein the carrier blocking layer is a hole blocking layer.

16. The ambipolar transistor device structure according to claim 15, wherein the hole blocking layer is formed of an inorganic material, and the inorganic material comprises LiF, CsF or TiO₂.

17. The ambipolar transistor device structure according to claim 15, wherein the hole blocking layer is formed of an organic material, and the organic material comprises 2,9-dimethyl-4,7-diphenyl-1,10-phenanthroline (BCP).

18. A method of forming an ambipolar transistor device structure, comprising:
forming a source and a drain on a substrate;
forming a carrier blocking layer and an ambipolar semiconductor layer on the substrate and at least between the source and the drain;
forming a dielectric layer on the ambipolar semiconductor layer; and
forming a gate on the dielectric layer between the source and the drain, wherein the dielectric layer isolates the gate, the source and the drain from each other.

19. The method of forming an ambipolar transistor device structure according to claim 18, wherein the step of forming the carrier blocking layer and the ambipolar semiconductor layer comprises:
forming a carrier blocking material layer, an ambipolar semiconductor material layer and a patterned photoresist layer on the substrate;
performing an etching process on the carrier blocking material layer and the ambipolar semiconductor material layer by using the patterned photoresist layer as a mask, so as to remove a portion of the carrier blocking material layer and a portion of the ambipolar semiconductor material layer; and
removing the patterned photoresist layer.

20. The method of forming an ambipolar transistor device structure according to claim 19, wherein the step of forming the carrier blocking material layer comprises performing an evaporation method.

21. The method of forming an ambipolar transistor device structure according to claim 19, wherein the step of forming the ambipolar semiconductor material layer comprises performing an evaporation method, a co-evaporation method, a sputtering method or a solution process.

22. The method of forming an ambipolar transistor device structure according to claim 18, wherein the ambipolar semiconductor layer is formed by stacking an N-type organic semiconductor material and a P-type organic semiconductor material.

23. The method of forming an ambipolar transistor device structure according to claim 18, wherein the ambipolar semiconductor layer is formed by mixing an N-type organic semiconductor material and a P-type organic semiconductor material.

24. The method of forming an ambipolar transistor device structure according to claim 18, wherein the ambipolar semiconductor layer is formed of an organic semiconductor material with an ambipolar property.

25. The method of forming an ambipolar transistor device structure according to claim 18, wherein the ambipolar semiconductor layer is formed by stacking an N-type inorganic semiconductor material and a P-type inorganic semiconductor material.

26. The method of forming an ambipolar transistor device structure according to claim 18, wherein the carrier blocking layer is an electron blocking layer.

27. The method of forming an ambipolar transistor device structure according to claim 26, wherein the electron blocking layer is formed of an inorganic material, and the inorganic material comprises WO₃, V₂O₅ or MoO₃.

28. The method of forming an ambipolar transistor device structure according to claim 26, wherein the electron blocking layer is formed of an organic material, and the organic material comprises 4′,4″-tris(N-3-methylphenyl-N-phenylamino)triphenylamine (m-MTDATA) or bis(2-methyl-8-quinolinolato-N1,O8)-(1,1′-biphenyl-4-olato) aluminum (BALq).

29. The method of forming an ambipolar transistor device structure according to claim 18, wherein the carrier blocking layer is a hole blocking layer.

30. The method of forming an ambipolar transistor device structure according to claim 29, wherein the hole blocking layer is formed of an inorganic material, and the inorganic material comprises LiF, CsF or TiO₂.

31. The method of forming an ambipolar transistor device structure according to claim 29, wherein the hole blocking layer is formed of an organic material, and the organic material comprises 2,9-dimethyl-4,7-diphenyl-1,10-phenanthroline (BCP).

32. A method of forming an ambipolar transistor device structure, comprising:
providing a substrate, wherein the substrate has a first region and a second region;
forming a first source and a first drain on the substrate in the first region;
forming a first carrier blocking material layer, an ambipolar semiconductor material layer and a second carrier blocking material layer on the substrate in the first region and the second region;
patterning the first carrier blocking material layer, the ambipolar semiconductor material layer and the second carrier blocking material layer, so as to form a first stack structure covering the first source and the first drain on the substrate in the first region and form a second stack structure on the substrate in the second region;
forming a second source and a second drain on the second stack structure;
forming a dielectric layer on the substrate to cover the first stack structure and the second stack structure; and
forming a first gate on the dielectric layer between the first source and the first drain and forming a second gate on the dielectric layer between the second source and the second drain.

33. The method of forming an ambipolar transistor device structure according to claim 32, wherein the step of patterning the first carrier blocking material layer, the ambipolar semiconductor material layer and the second carrier blocking material layer comprises:
forming a patterned photoresist layer on the second carrier blocking material layer;
removing a portion of the first carrier blocking material layer, a portion of the ambipolar semiconductor material layer and a portion of the second carrier blocking material layer by using the patterned photoresist layer as a mask; and
removing the patterned photoresist layer.

34. The method of forming an ambipolar transistor device structure according to claim 32, wherein the step of forming the first carrier blocking material layer or the second carrier blocking material layer comprises performing an evaporation method.

35. The method of forming an ambipolar transistor device structure according to claim 32, wherein the step of forming the ambipolar semiconductor material layer comprises performing an evaporation method, a co-evaporation method or a solution process.

36. The method of forming an ambipolar transistor device structure according to claim 32, wherein the ambipolar semiconductor material layer is formed by stacking an N-type organic semiconductor material and a P-type organic semiconductor material.

37. The method of forming an ambipolar transistor device structure according to claim 32, wherein the ambipolar semiconductor material layer is formed by mixing an N-type organic semiconductor material and a P-type organic semiconductor material.

38. The method of forming an ambipolar transistor device structure according to claim 32, wherein the ambipolar semiconductor material layer is formed of an organic semiconductor material with an ambipolar property.

39. The method of forming an ambipolar transistor device structure according to claim 32, wherein the ambipolar semiconductor material layer is formed by stacking an N-type inorganic semiconductor material and a P-type inorganic semiconductor material.

40. The method of forming an ambipolar transistor device structure according to claim 32, wherein
when the first region is a P-type device region and the second region is an N-type device region, the first carrier blocking material layer is an electron blocking material layer, and the second carrier blocking material layer is a hole blocking material layer; or
when the first region is an N-type device region and the second region is a P-type device region, the first carrier blocking material layer is a hole blocking material layer, and the second carrier blocking material layer is an electron blocking material layer.

41. The method of forming an ambipolar transistor device structure according to claim 32, wherein when the first carrier blocking material layer or the second carrier blocking material layer is an electron blocking material layer, the electron blocking material layer is formed of an inorganic material or an organic material.

42. The method of forming an ambipolar transistor device structure according to claim 41, wherein the inorganic material comprises WO₃, V₂O₅ or MoO₃.

43. The method of forming an ambipolar transistor device structure according to claim 41, wherein the organic material comprises 4′,4″-tris(N-3-methylphenyl-N-phenylamino)triphenylamine (m-MTDATA) or bis(2-methyl-8-quinolinolato-N1,O8)-(1,1′-biphenyl-4-olato) aluminum (BALq).

44. The method of forming an ambipolar transistor device structure according to claim 32, wherein when the first carrier blocking material layer or the second carrier blocking material layer is a hole blocking material layer, the hole blocking material layer is formed of an inorganic material or an organic material.

45. The method of forming an ambipolar transistor device structure according to claim 44, wherein the inorganic material comprises LiF, CsF or TiO₂.

46. The method of forming an ambipolar transistor device structure according to claim 44, wherein the organic material comprises 2,9-dimethyl-4,7-diphenyl-1,10-phenanthroline (BCP).

47. A method of forming an ambipolar transistor device structure, comprising:
forming an ambipolar semiconductor layer and a carrier blocking layer on a substrate;
forming a source and a drain on the carrier blocking layer;
forming a dielectric layer on the substrate to cover the source and the drain; and
forming a gate on the dielectric layer between the source and the drain.

48. A method of forming an ambipolar transistor device structure, comprising:
forming a gate on a substrate;
forming a dielectric layer on the substrate to cover the gate;
forming a source and a drain on the dielectric layer at two sides of the gate; and
forming a carrier blocking layer and an ambipolar semiconductor layer on the dielectric layer and at least between the source and the drain.

49. A method of forming an ambipolar transistor device structure, comprising:
forming a gate on a substrate;
forming a dielectric layer on the substrate to cover the gate;
forming an ambipolar semiconductor layer and a carrier blocking layer on the dielectric layer; and
forming a source and a drain on the carrier blocking layer at two sides of the gate.

50. A method of forming an ambipolar transistor device structure, comprising:
providing a substrate, wherein the substrate has a first region and a second region;
forming a first gate on the substrate in the first region and forming a second gate on the substrate in the second region;
forming a dielectric layer on the substrate to cover the first gate and the second gate;
forming a first source and a first drain on the dielectric layer in the first region;
forming a first carrier blocking material layer, an ambipolar semiconductor material layer and a second carrier blocking material layer on the substrate in the first region and the second region;
patterning the first carrier blocking material layer, the ambipolar semiconductor material layer and the second carrier blocking material layer, so as to form a first stack structure covering the first source and the first drain on the substrate in the first region and form a second stack structure on the substrate in the second region; and
forming a second source and a second drain on the second stack structure.
